(19) United States
(12) Patent Application Publication
(10) Pub. No.: US 2005/0287689 A1
(43) Pub. Date: Dec. 29, 2005

(54) Method for manufacturing carbon fibers, method for manufacturing electron-emitting device using the same, method for manufacturing electronic device, method for manufacturing image display device, and information display reproduction apparatus using the same

(75) Inventors: Takashi Iwaki, Tokyo (JP); Takeo Tsukamoto, Kanagawa-Ken (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/150,207

(22) Filed: Jun. 13, 2005

(30) Foreign Application Priority Data
Jun. 23, 2004 (JP) 185026/2004

(51) Int. Cl. H01L 21/00; H01L 27/15; H01L 29/26; H01L 31/12; H01L 33/00

(52) U.S. Cl. 438/22; 257/79

(57) ABSTRACT

Carbon fibers having superior properties are very uniformly formed on a substrate. A method for manufacturing carbon fibers is provided which has the steps of disposing laminates formed of a first catalyst material and particles containing a second catalyst material on the substrate, causing a reaction between the first and the second catalyst materials to form catalyst particles therefrom, and causing a reaction between the catalyst particles thus obtained and a raw material for the carbon fibers. As a result, the carbon fibers are formed on the substrate.

### BACKGROUND OF THE INVENTION

1. Field of the Invention

The present invention relates to a method for manufacturing a carbon fiber, a method for manufacturing an electron-emitting device using the same, a method for manufacturing an electronic device, a method for manufacturing an image display device, and an information display reproduction apparatus using the image display device.

2. Description of the Related Art

Various methods for manufacturing a carbon fiber on a substrate have already been disclosed. For example, a method has been disclosed having the steps of forming a catalyst layer on a substrate, aggregating this catalyst layer by reduction to form catalyst particle on the substrate, and pyrolyzing a carbon compound such as a hydrocarbon using the catalyst particle to form a carbon fiber at the location of the catalyst particle.

In addition, methods for growing a carbon fiber by using a catalyst containing a plurality of metals have been disclosed in Japanese Patent Laid-Open Nos. 3-260119, 2002-115057, 2002-150925, and 2004-115959, and U.S. Pat. No. 5,973,444. In recent years, a technique has drawn attention in which a carbon fiber grown using a catalyst are used for an electron-emitting device (see Japanese Patent Laid-Open Nos. 2002-150925 and 2004-115959, and U.S. Pat. No. 5,973,444).

### SUMMARY OF THE INVENTION

In the methods described above in which the catalyst particles are formed from the catalyst layer, the properties of the catalyst particles provided on the substrate, such as a density of the particles, spaces between the particles, diameters of the particles, and a composition (alloy composition) of the particles, have not been always easily controlled.

In particular, it has been difficult to reproducibly dispose catalyst particle (typically, catalyst particle of alloy) having a desired composition and shape on a substrate, the catalyst particle containing many types of metals so as to form a carbon fiber having favorable properties. As a result, it has been difficult to reproducibly form a plurality of carbon fibers having a good uniformity and superior properties on a substrate by a simple method.

Hence, a method has been desired which simultaneously controls the arrangement of carbon fibers by controlling the density of catalyst particles, the diameter of the carbon fibers by controlling the particle diameter of the catalyst particles, and the properties such as crystallinity of the carbon fibers by controlling the composition (alloy composition) of the catalyst particles. In addition, for controllably manufacturing carbon fibers having good properties as an electron emission material used for an electron-emitting device, a method has been particularly desired which can dispose alloy catalyst particles on a substrate without using any complicated process.

The present invention provides a method for manufacturing a carbon fiber having good properties using catalyst particle preferably disposed on a substrate, the catalyst particle having a good shape and containing many catalyst materials to form a desired composition, a method for forming an electron-emitting device using the carbon fiber described above, and a method for manufacturing an electronic device, and a method for manufacturing an image display device using the electron-emitting device described above.

In accordance with a first aspect of the present invention, there is provided a method for manufacturing a carbon fiber, comprising a first step of bringing a first catalyst material into contact with a particulate second catalyst material on a substrate, the first catalyst material and the second catalyst material being different from each other, a second step of causing the first catalyst material and the second catalyst material to react with each other to form a catalyst particle on the substrate, and a third step of growing a carbon fiber on the substrate using the catalyst particle.

In the method described above, the first step can comprise a first substep of disposing the first catalyst material on the substrate to form a film, and a second substep of disposing a particle containing the second catalyst material on the first catalyst material. Alternatively, in the method described above, the first step can comprise a first substep of disposing a particle containing the second catalyst material on the substrate, and a second substep of disposing the first catalyst material so as to cover the particle. In the case described above, the first step comprises the step of bringing a magnetic first catalyst material into contact with a particulate, non-magnetic second catalyst material. The first substep described above may comprise a step of disposing a plurality of a particles on the substrate, each of which contains the second catalyst material, and the second substep described above may comprise a step of disposing the first catalyst material so that the particles are not connected with each other through the first catalyst. The second substep described above may comprise a step of precipitating the first catalyst material on the particles by bringing the particles into contact with a solvent containing the first catalyst material. In the method according to the first aspect of the present invention, the first step comprises the step of bringing an iron-containing, a nickel-containing, or a cobalt-containing first catalyst material into contact with a palladium-containing second catalyst material. In addition, in the method described above, the second step comprises a step of forming a catalyst particle comprising an alloy composed of the first catalyst material and the second catalyst material.

Furthermore, in accordance with second to fourth aspects of the present invention, there are provided a method for manufacturing an electronic device having a carbon fiber, a method for manufacturing an electron-emitting device having a carbon fiber, and a method for manufacturing an image display device. The method for manufacturing an electronic device having a carbon fiber comprises a step of manufacturing at least one component of the electronic device, and a step of manufacturing the carbon fiber. The step of manufacturing the carbon fiber comprises a first step of bringing a first catalyst material into contact with a particulate second catalyst material on a substrate, the first catalyst material and the second catalyst material being different from each other, a second step of causing the first catalyst material and the second catalyst material to react with each other to form a catalyst particle on the substrate, and a third step of growing the carbon fiber on the substrate using the catalyst particle. The method for manufacturing an electron-emitting device having a carbon fiber, comprises a step of forming the carbon fiber and a step of manufacturing at least one additional component of the electron-emitting device configured and positioned to cause electrons to be emitted from the carbon fiber. The step of forming the carbon fiber comprises a first step of bringing a first catalyst material into contact with a particulate second catalyst material on a substrate, the first catalyst material and the second catalyst material being different from each other, a second step of causing the first catalyst material and the second catalyst material to react with each other to form a catalyst particle on the substrate, and a third step of growing the carbon fiber on the substrate using the catalyst particle. The method for manufacturing an image display device comprises the steps of manufacturing a plurality of electron-emitting devices, and manufacturing a light-emitting member emitting light in response to irradiation with electrons emitted from the plurality of electron-emitting devices. Each of the electron-emitting devices is manufactured by a step of forming a carbon fiber and a step of manufacturing at least one additional component of the electron-emitting device configured and positioned to cause electrons to be emitted from the carbon fiber. The step of forming the carbon fiber comprises a first step of bringing a first catalyst material into contact with a particulate second catalyst material on a substrate, the first catalyst material and the second catalyst material being different from each other, a second step of causing the first catalyst material and the second catalyst material to react with each other to form a catalyst particle on the substrate, and a third step of growing the carbon fiber on the substrate using the catalyst particle.

In addition, in accordance with a fifth aspect of the present invention, there is provided a method of manufacturing an information display reproduction apparatus comprising the steps of manufacturing a receiver which outputs at least one of an image signal, a character signal, and an audio signal contained in a received broadcasting signal, and manufacturing an image display device connected to the receiver and displaying an image in response to receiving the image signal or the character signal from the receiver. The image-display-device manufacturing step comprises the steps of manufacturing a plurality of electron-emitting devices and manufacturing a light-emitting member emitting light in response to irradiation with electrons emitted form the plurality of electron-emitting devices. The plurality of electron-emitting devices are manufactured by a step of forming a carbon fiber and a step of manufacturing at least one additional component of the electron-emitting device configured and positioned to cause electrons to be emitted from the carbon fiber. The step of forming the carbon fiber comprises a first step of bringing a first catalyst material into contact with a particulate second catalyst material on a substrate, the first catalyst material and the second catalyst material being different from each other, a second step of causing the first catalyst material and the second catalyst material to react with each other to form a catalyst particle on the substrate, and a third step of growing the carbon fiber on the substrate using the catalyst particle. And in accordance with a sixth aspect of the present invention, there is provided an image display reproduction apparatus, comprising a receiver configured to output at least one of an image signal, a character signal, and an audio signal contained in a received broadcast signal, and an image display device connected to the receiver and configured to display an image in response to receiving the image signal or the character signal from the receiver. The image display device is manufactured according to the steps of manufacturing a plurality of electron-emitting devices and manufacturing a light-emitting member emitting light in response to irradiation with electrons emitted from the plurality of electron-emitting devices. Each of the plurality of electron-emitting devices is manufactured by a step of forming a carbon fiber and a step of manufacturing at least one additional component of the electron-emitting device configured and positioned to cause electrons to be emitted from the carbon fiber. The step of forming the carbon fiber comprises a first step of bringing a first catalyst material into contact with a particulate second catalyst material on a substrate, the first catalyst material and the second catalyst material being different from each other, a second step of causing the first catalyst material and the second catalyst material to react with each other to form a catalyst particle on the substrate, and a third step of growing the carbon fiber on the substrate using the catalyst particle.

According to the present invention, many catalyst particles having well-controlled particle diameter and alloy composition can be reproducibly disposed on a substrate with. controlled spaces provided between the particles, and when carbon fibers are grown using the above catalyst particles, many carbon fibers having superior electron emission properties can be disposed on the substrate.

Further features and advantages of the present invention will become apparent from the following description of exemplary embodiments with reference to the attached drawings.

### BRIEF DESCRIPTION OF THE DRAWINGS

FIGS. 1A to 1F are schematic cross-sectional views showing one example of a process for manufacturing an electron-emitting device according to the present invention.

FIGS. 2A and 2B are plan and cross-sectional schematic views, respectively, showing one example of a lateral-type electron-emitting device according to the present invention.

FIG. 3 is a schematic partially cross-sectional view showing the state in which the electron-emitting device shown in FIG. 2 is operated.

FIG. 4 is a graph showing electron emission properties of an electron-emitting device according to the present invention.

FIGS. 5A and 5B are schematic side views showing one example of the structure of carbon fibers according to the present invention and FIG. 5C is a schematic view of one embodiment of the graphenes comprising a carbon fiber.

FIGS. 6A and 6B are schematic side views showing another example of the structure of carbon fibers according to the present invention and FIG. 6C-1 and 6C-2 are schematic views of another embodiment of the graphenes comprising a carbon fiber.

FIG. 7 is a schematic partially cross-sectional view showing one example of a vertical electron-emitting device according to the present invention.

FIG. 8 is a schematic top view showing one example of an electron source according to the present invention.

FIG. 9 is a schematic perspective view showing one example of an image display device according to the present invention, with the face plate 130 partially cut away.

FIGS. 10A to 10C are schematic side views showing a method for manufacturing carbon fibers according to the present invention.

FIGS. 11A to 11E are schematic side views showing a method for manufacturing carbon fibers according to the present invention.

FIG. 12 is a schematic block diagram showing one example of an information display reproduction apparatus according to the present invention.

### DESCRIPTION OF THE EMBODIMENTS

Hereinafter, a method for manufacturing a carbon fiber and a method for manufacturing an electron-emitting device, according to the present invention, will be described. In the embodiments described below, the same reference numerals used in different figures denote the same or similar elements.

The “carbon fiber” in the present invention includes, for example, a carbon nanotube, a graphite nanofiber, an amorphous carbon fiber, and a diamond fiber. In addition, the “carbon fiber” is a fiber containing carbon and is preferably primarily formed of carbon. When the carbon fiber is used for an electronic device such as an electron-emitting device in which current is passed through the carbon fiber, the diameter of the carbon fiber is preferably in the range of 1 nm to 1 μm, more preferably in the range of 1 to 500 nm, and even more preferably in the range of 5 to 100 nm in order to achieve stable current supply. Furthermore, the length of the carbon fiber is preferably 5 times or more the diameter thereof.

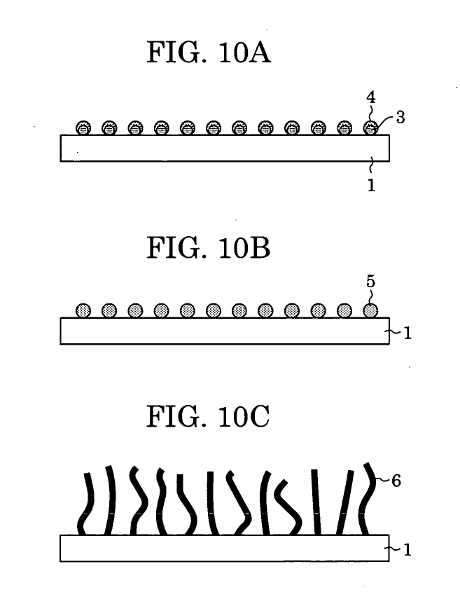

First, referring to FIGS. 10A to 10C, the method for manufacturing a carbon fiber, according to the present invention, will be briefly described. According to the present invention, the carbon fiber or carbon fibers can be basically formed by the following steps 1 to 3. In the step 1, a first catalyst material 4 and a particulate second catalyst material 3 different therefrom are brought into contact with each other on a substrate 1 (FIG. 10A). In the step 2, by reaction between the first catalyst material and the second catalyst material, catalyst particles 5 are formed from the first catalyst material and the second catalyst material on the substrate 1 (FIG. 10B). In the step 3, by using the catalyst particles 5 disposed on the substrate 1, carbon fibers 6 are grown on the substrate 1 using a raw material for the carbon fibers (FIG. 10C).

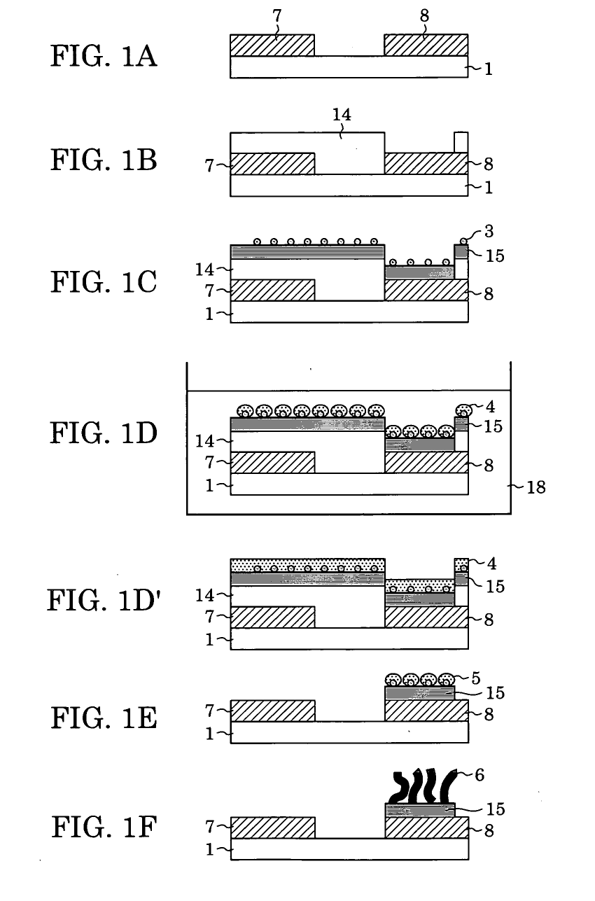

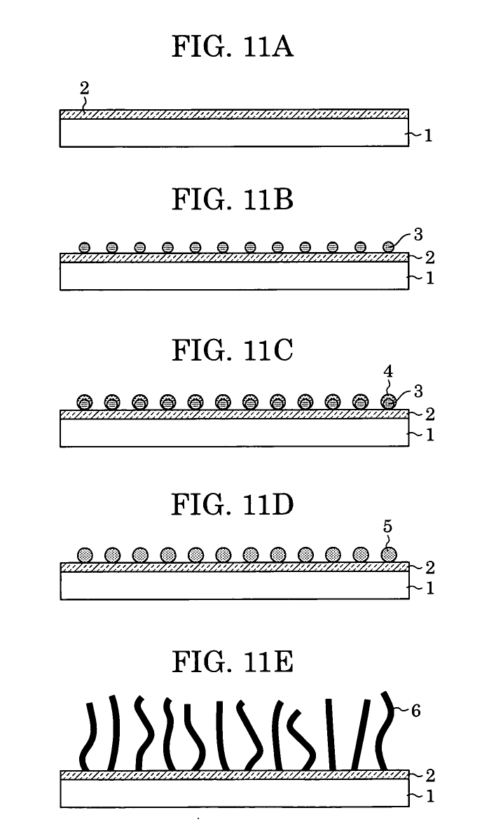

Hereinafter, the above individual steps will be described in detail with reference to FIGS. 11A to 1E.

(Step 1)

The substrate 1 shown in FIG. 10A may also have an electrode (conductive film) 2 on the surface thereof as shown in FIG. 11A. In particular, when the carbon fibers formed in the step 3 are used for an electronic device, the substrate 1 preferably has at least the electrode (conductive film) 2 on the surface. However, when the substrate 1 is formed of a conductive material, such as a metal, the electrode (conductive film) 2 is not always necessary. As a material for the substrate 1, although various materials may be used, glass is preferably used. When glass is used as the material for the substrate 1, and the carbon fibers are used for an electronic device, the electrode (conductive film) 2 is preferably provided on the surface of the substrate 1.

In addition, when a material forming the substrate 1 (or the electrode 2) is liable to chemically react with the first catalyst material and/or the second catalyst material, a layer having a lower reactivity with the first catalyst material and/or the second catalyst material than that of the substrate 1 (or the electrode 8) is preferably provided on the surface thereof. When the carbon fibers formed on the substrate 1 (or the electrode 8) are directly used for an electronic device such as an electron-emitting device, as the layer described above, a conductive material layer having a lower reactivity with the first and/or second catalysts is preferably used. As a preferable material forming the layer (conductive material layer) having the properties as described above, for example, a transition metal nitride may be used. As the transition metal nitride, for example, TiN, ZrN, TaN, HfN, VN, and CrN may be used. In addition, an oxide such as TiOx may also be used when it has a small thickness. Furthermore, when the intermediate layer (a layer having a lower reactivity with the first and/or second catalysts) as described above is disposed between the electrode and the catalyst, the range of selection of electrode materials can be increased.

A step of bringing the first catalyst material 4 into contact with the particulate second catalyst material 3 (in other words, a step of forming laminated bodies (laminated members) containing the first catalyst material 4 and the particle 3 containing the second catalyst material) can be performed by the following procedure. That is, the particles 3 containing the second catalyst material are disposed on the substrate 1 (or the electrode 2) (FIG. 11B). Next, the particles 3 containing the second catalyst material are covered with the first catalyst material 4 (FIG. 11C). By the substep described above, the first catalyst material 4 and the particles 3 containing the second catalyst material can be brought into contact with each other on the substrate. As described above, the structure formed by the contact between the first catalyst material 4 and the particles 3 containing the second catalyst material is called in the present invention a “laminated body (or a laminated member) of the first catalyst material 4 and the particle 3 containing the second catalyst material” or is simply called a “laminated body” or a “laminated member”. In addition, when many laminated bodies formed of the particles 3 containing the second catalyst material and the first catalyst material 4 are disposed, the laminated bodies are disposed on the substrate 1 (or the electrode 2) with spaces provided therebetween.

The step of bringing the first catalyst material 4 into contact with the particulate second catalyst material 3 may also be performed by disposing a film containing the first catalyst material 4 on the substrate 1 (or the electrode 2), and disposing the particles 3 containing the second catalyst material on the first catalyst material 4.

In consideration of the diameter of the above-mentioned carbon fiber, the diameter of the particle containing the second catalyst material is preferably set in the range of 1 nm to less than 100 nm. In addition, the particles containing the second catalyst material preferably have a narrow distribution of their particle diameter.

As a method for disposing the particle containing the second catalyst material, the particle containing the second catalyst material prepared beforehand are preferably disposed on the substrate 1 (or the electrode 2). In addition, as a particular method for disposing the particles containing the second catalyst material, for example, a method for applying a dispersion liquid including the particles containing the second catalyst material, or a method for disposing the particles containing the second catalyst material by a gas deposition technique may be used.

When the method for applying a dispersion liquid including the particles containing the second catalyst material is used, for example, after the dispersion liquid is applied onto the substrate 1 (or the electrode 2), unnecessary materials such as a solvent are removed by heating, and then the particles thus treated are reduced, thereby disposing the particles on the substrate 1 (or the electrode 2). It is preferable to use the method described above because the spaces between the particles on the substrate 1 (or the electrode 2) can be easily adjusted by adjusting the concentration of the particles in the dispersion liquid and/or by adjusting the conditions for applying the dispersion liquid onto the substrate 1 (or the electrode 2).

Alternatively, when a film made of the second catalyst material is formed on the substrate 1 (or the electrode 2), followed by heating of the film for aggregation, disposing the particles containing the second catalyst material on the substrate 1 (or the electrode 2) may also be performed. The film made of the second catalyst material can be formed by a known method such as a sputtering method or a method in which a solution of the second catalyst material (such as a complex solution of the second catalyst material) is applied onto the substrate 1 (or the electrode 2), followed by baking. As a primary solvent of the solution of the second catalyst material described above, water is preferably used in view of production efficiency.

When the particles containing the second catalyst material are disposed on the first catalyst material, a method may be used in which after the first catalyst material is provided on the substrate 1 (or the electrode 2), the particles containing the second catalyst material are disposed on the first catalyst material by the method described above.

A protective agent may be added to the dispersion liquid of the particles 3 containing the second catalyst material, to curb the aggregation of the particles. As the protective agent, a polymer (molecular weight is typically 10,000 or more), a surfactant, or a metal ligand may be used. After the dispersion liquid is applied onto the substrate 1 (or the electrode 2), the protective agent can be removed by heating. Should the catalytic ability of the particles 3 be impaired, for example, when the particles 3 are oxidized by heating treatment to remove a solvent or protective agent, the catalytic ability of the particles 3 can be easily restored by the reducing treatment described above. It should be noted that the reducing treatment is not always necessary when a material forming the particles 3 is unlikely to be oxidized.

In addition, by the above heating treatment, adhesiveness between an underlayer (that is, the substrate 1 (or the electrode 2) or the first catalyst material) and the particles 3 containing the second catalyst material can be improved.

The arrangement (such as spaces between the particles 3 containing the second catalyst material) of the particles 3 on the substrate 1 (or the electrode 2) can be adjusted by controlling the concentration of the dispersed liquid containing the particles 3.

Although depending on the method for applying a dispersion liquid of the particles 3 containing the second catalyst material, in general, the concentration of the particles 3 in the dispersion liquid is preferably 1 percent by weight or less (1 wt % or less). In addition, the concentration of the particles 3 in the dispersion liquid is preferably 0.005 percent by weight or more (0.005 wt % or more). When the concentration is more than 1 percent by weight, the particles 3 are likely to form a film on the substrate 1 (or the electrode 2), and when the concentration is less than 0.005 percent by weight, the spaces between the particles 3 are excessively increased. As a result, the distribution density of the carbon fibers 6 formed in the step 3 becomes excessively small, and hence the range of the concentration described above is suitable for practical use.

In consideration of the quality of the carbon fiber 6 to be obtained and also in consideration of the electron emission properties thereof, the catalyst particle 5 obtained in the step 2 preferably contains at least two catalyst materials selected from the group consisting of Fe, Co, Ni, Pd, Y, Rh, Pt, La, Ce, Pr, Nd, Gd, Tb, Dy, Ho, Er, and Lu. In particular, in order to obtain carbon fiber having desirable properties, as the second and the first catalyst materials, Pd and one of Fe, Co, and Ni are preferably selected, respectively. Among those mentioned above, the combination of Pd and Co is more preferably used since these elements permit the manufacture of a carbon fiber that maintains desirable electron-emission properties for a long period of time.

As described above, the first and the second catalyst materials of the present invention are preferably metals. In addition, the catalyst particles 5 obtained in the step 2 are preferably an alloy formed of at least two catalyst materials selected from the aforementioned catalyst materials. Hence, the first and the second catalyst materials are each selected from the aforementioned materials. In addition, the first catalyst material is a material different from the second catalyst material.

When one of the first and the second catalyst materials described above is a magnetic material, and the other is a non-magnetic material, the non-magnetic material and the magnetic material are preferably used as the second catalyst material and the first catalyst material, respectively.

The case described above is particularly preferable when a dispersion liquid of the particles 3 containing the second catalyst material is applied onto the substrate 1 (or the electrode 2) or onto the first catalyst material.

That is, the reason for this is that the arrangement of a magnetic material is difficult to control due to its magnetic properties. For example, when particles of a magnetic material are used in the dispersion liquid, the particles tend to aggregate in the solvent and/or on the substrate 1. As a result, it becomes difficult to secure desired spaces between the particles or to obtain a desired distribution density thereof on the substrate 1.

Hence, of the first and the second catalyst materials, when one catalyst material is a magnetic material, and the other catalyst material is a non-magnetic material, the first catalyst material and the second catalyst material are preferably a magnetic material and a non-magnetic material, respectively. As the magnetic catalyst material described above, Fe, Co, or Ni may be used. In addition, as the non-magnetic material, in consideration of the properties of the carbon fiber, palladium is preferably used.

Accordingly, in consideration of the quality of the carbon fiber 6 to be obtained and also in consideration of the electron emission properties thereof, it is particularly preferable that the first catalyst material and the second catalyst material be Co and Pd, respectively.

In addition, the first catalyst material preferably forms a film covering the particles containing the second catalyst material. When the first catalyst material forms a film, particles 5 containing the first and second catalyst material can be almost exclusively obtained in regions where the particles 3 containing the second catalyst material and the film of the first catalyst material are overlapped with each other. In addition, the film of the first catalyst material may be composed of island-shape films.

In addition, as a method for forming the first catalyst material 4 on the substrate 1 (or the electrode 2) or the particles 3 containing the second catalyst material, when a solution of the first catalyst material is used, for example, a spin coating method, a dipping method, spraying method, or an ink-jet method may be used.

In the case in which a solution composed of a solvent and the first catalyst material dissolved therein is used, when Fe is used as the first catalyst material, for example, iron carboxylates, such as iron acetylacetonates, iron acetate, iron octylate, iron stearate, and iron oxalate, may be used as compounds containing Fe to be dissolved in the solvent. In addition, when Co is used as the first catalyst material, for example, cobalt carboxylates, such as cobalt acetylacetonates, cobalt acetate, cobalt naphthenate, and cobalt oxalate, may be used. In addition, when Ni is used as the first catalyst material, as compounds containing Ni, for example, cobalt carboxylates, such as nickel acetylacetonates, nickel acetate, nickel formate, and nickel stearate, may be used as compounds containing Co to be dissolved in the solvent.

The compounds mentioned above may also be in the form of a complex in which a ligand is coordinated. Although a compound having a coordinating oxygen (O) atom and a compound having a coordinating nitrogen (N) atom may be mentioned, compounds, such as amines, alcohol amines, and ethylene diamines, having a coordinating nitrogen (N) atom are preferably used.

When the solution is applied, in order to improve dispersibility and paintability of an organic metal compound, a solution containing a polymer compound, molecular weight of which is typically 10,000 or more, or an alcohol is preferably used.

In addition, as shown in FIGS. 11B and 11C, when the first catalyst material 4 is disposed on the individual particles 3 containing the second catalyst material, laminated body can be formed by precipitating (depositing) the first catalyst material 4 on the particles 3 containing the second catalyst material. That is, the particles 3 containing the second catalyst material are each used as a plating nucleus, and the first catalyst material is precipitated (deposited) thereon by a plating method.

The first catalyst material and the second catalyst material may independently work as nuclei or catalysts for growing carbon fibers. Hence, the temperature for growing the carbon fiber in the step 3, which will be described later, must be carefully determined in consideration of the state in which the particle 3 containing the second catalyst material and the first catalyst material 4 are overlapped with each other. That is, when a region in which only one of the first catalyst material and the second catalyst material is disposed is present on the substrate 1 (or the electrode 2), depending on the temperature in the step 3, carbon fiber may also be grown in the region described above. Accordingly, the case described above is not preferable.

Hence, a method is preferably used in which the particles 3 containing the second catalyst material are each used as a plating nucleus and the first catalyst material 4 is precipitated thereon. By the method described above, the particles 3 containing the second catalyst material 3 can be disposed on the substrate 1 (or the electrode 2) with desired spaces (distribution density) provided therebetween, and in addition, only on the particles 3 containing the second catalyst material disposed with the desired spaces therebetween, the films of the first catalyst material 4 can be selectively formed. The thickness of the first catalyst material 4 can be controlled by the time for precipitating (plating) the first catalyst material 4, and hence, by the films of the first catalyst material 4, the particles 3 containing the second catalyst material are prevented from being brought into contact with each other. Hence, the particles 5 formed from the first catalyst material and the second catalyst material in the step 2 can be disposed on the substrate 1 (or the electrode 2) with desired spaces (distribution density) therebetween.

In particular, after the particles 3 containing the second catalyst material are disposed on the substrate 1 (or the electrode 2), this substrate 1 is immersed in an electrolytic plating bath, so that the first catalyst material 4 is precipitated (plated) on the surfaces of the particles 3 containing the second catalyst material using an electrolytic plating method.

The electrolytic plating bath is an aqueous solution generally containing a metal salt, a reducing agent, a pH regulator, a buffer, a completing agent, a stabilizer, and the like. The reducing agent may be selected from, for example, sodium hypophosphite, sodium boron hydride, or hydrazine. In addition, in order to increase the life of the plating bath and/or to improve the efficiency of the reducing agent, for example, a pH regulator, a buffer, a complexing agent, and a stabilizer may be used.

The pH regulator may be selected from, for example, an inorganic acid, an organic acid, or a basic compound, such as sodium hydroxide or ammonium hydroxide.

The buffer is used for suppressing the variation in pH, and as the buffer, for example, there may be mentioned a sodium carboxylate, such as sodium citrate or sodium acetate, an inorganic salt of boric acid, carbonic acid, or the like, or a metal salt of an organic acid, inorganic acid, or the like. As the complexing agent, for example, sodium citrate, sodium acetate, ammonium, ethylene diamine glycine, or pyridine may be mentioned.

The complexing agent may decrease the concentration of free metal ions so as to prevent the precipitation of hydroxides, and as a result, the stability of the bath is improved.

When a powdered metal is precipitated in a plating solution or a reducing reaction occurs in a region other than the surface of a workpiece to be plated, the plating solution may be decomposed. Hence, as a stabilizer for preventing the decomposition, a small amount of a sulfur compound or lead ions may be added in some cases for preferential adsorption so as to suppress the decomposition of the plating solution.

For example, an electrolytic cobalt plating bath may be used as the electrolytic plating bath when Co is used as the first catalyst material 4. It is preferable that cobalt chloride is used as a metal salt contained in the electrolytic cobalt plating bath, hydrazine hydrochloride is used as the reducing agent, sodium tartrate is used as the complexing agent, and pH is set to 10 or more.

Laminated bodies (as shown in FIGS. 10A and 11C) composed of the Co layers 4 and the Pd particles 3 covered therewith are formed on the substrate 1 by immersing the substrate 1 having the particles 3 (such as Pd particles) containing the second catalyst material thereon in the electrolytic cobalt plating bath.

In addition, the amount (film thickness) of the first catalyst material 4 precipitated (deposited) on the surface of the particle 3 containing the second catalyst material 3 can be controlled by adjusting the temperature of the electrolytic plating bath, the immersion time, and the like.

As described above, the laminated bodies, each of which is composed of the first catalyst material 4 and the particle 3 containing the second catalyst material, can be disposed on the substrate 1 (or the electrode 2) (FIG. 10A).

Heretofore, the case was described in which only two types of catalyst materials were used; however, a third catalyst material and/or a material not having a catalytic activity function may also be contained in the above laminated body (laminated member). That is, for example, a third catalyst material may also be contained in the particles 3 containing the second catalyst material, or a third catalyst material may also be formed on the film of the first catalyst material 4 stacked on the particle 3. Alternatively, a mixture of the first catalyst material 4 and a third catalyst material may also be provided on the particle 3. It should be noted that, in the present invention, the “particulate second catalyst material” naturally represents the second catalyst material in the form of particle; however, in addition, it also represents a particulate substance containing the second catalyst material or a particle containing the second catalyst material. Hence, the “particle containing the second catalyst material” and the “particulate second catalyst material” are substantially equivalent to each other. Accordingly, the “particulate second catalyst material” also includes a particulate substance containing another catalyst material or a material having no catalytic function besides the second catalyst material. In the present invention described above, the laminated bodies comprising the first catalyst material 4 and the particles 3 (particulate second catalyst material) containing the second catalyst material are disposed on the substrate 1 (or the electrode 2).

In addition, as described above, in the present invention, depending on the temperature for growing the carbon fibers in the step 3 which will be described later, it is not preferable to dispose the first catalyst material. on part of the substrate 1 (or the electrode 2) which is exposed between the particles 3.

However, when the first catalyst materials and the second catalyst material are appropriately selected so that the temperature of the first catalyst material itself required for starting the growth of the carbon fiber is effectively higher by 30° C. or more than the temperature of the second catalyst material itself required for starting the growth of the carbon fiber, in this step 1, no problems may occur at all even when the first catalyst material is present on the parts of the substrate 1 (or the electrode 2) which are exposed between the particles 3 containing the second catalyst material. Hence, when the first catalyst materials and the second catalyst material are selected as described above, the manufacturing method is not limited to the above plating method, and as a result, various methods may be more freely selected.

In addition, in consideration of the growth of the carbon fibers, more precisely, the temperature of the particle 5 required for starting the growth of the carbon fiber, the particle 5 being formed from the first and the second catalyst materials in the step 2, must be compared to that of the first catalyst material.

Hence, when the temperature required for starting the growth of a carbon fiber, in the case in which only the first catalyst material is used, is preferably set to be effectively higher than the temperature required for starting the growth of a carbon fiber in the case in which the particle 5 (typically, an alloy particle of the first and the second catalyst materials) formed from the first and the second catalyst materials in the step 2 is used, no problems may occur at all in this step even when the first catalyst material is present on part of the substrate 1 (or the electrode 2) exposed between the particles 3 containing the second catalyst material. The difference in temperature is set to 30° C. or more and is preferably set to 100° C. or more.

In this embodiment, “the temperature required for starting the growth of the carbon fiber” may be defined as the minimum temperature at which the carbon fibers can be grown to have a length of 1 μm or more within 30 minutes by using a catalyst material in a system in which, for example, a raw material gas for forming the carbon fiber, the partial pressure of the raw material gas, and the diameter of a catalyst particle are each maintained at a constant value.

(Step 2)

The particles 5 described with reference to FIG. 10B can be obtained by heating the substrate 1 on which the laminated bodies typically formed of the first catalyst material 4 and the particles 3 containing the second catalyst material are disposed. In addition, the first and the second catalyst materials, which are contained in the catalyst particle 5, preferably form an alloy of the first and the second catalyst materials.

As a method for causing a reaction between the first and the second catalyst materials, a method may be performed in which the laminated bodies formed of the first catalyst material and the particles of the second catalyst material are disposed on the substrate, followed by heating. The heating is preferably performed in a non-oxidizing atmosphere. As a method for causing the reaction between the first and the second catalyst materials by heating in a non-oxidizing atmosphere, for example, heating is performed at 500 to 700° C. in a vacuum environment.- In this case, even when the first catalyst material and/or the second catalyst material in the form of a metal compound is disposed on the substrate 1, the metal compound is decomposed, so that the catalyst particles 5 (catalyst particles 5 made of an alloy of the first and second catalysts) can be formed. As the method for causing the reaction between the first and the second catalyst materials, a method may also be used in which heating is performed in an oxidizing atmosphere, followed by heating in a reducing atmosphere. In this method, for example, after the laminated bodies of the first catalyst material and the particles 3 are heated in air to a range of 200 to 500° C. or more, preferably to approximately 350° C., to form an oxide, heating is performed in a hydrogen atmosphere at 500 to 700° C. so as to reduce the oxide, thereby forming the alloy catalyst particles 5 formed from the first and the second catalyst materials (metals).

In this way, the catalyst particles 5 made by reacting the first catalyst material with the second catalyst material can be disposed on the substrate 1 (or the electrode 2).

In view of the electron emission properties, the catalyst particle 5 contains preferably Pd and one of Fe, Co, and Ni. More preferably, the catalyst particle 5 contains an alloy of Pd and Co. In addition, 20 atomic percent or more of one element of Fe, Co, and Ni is preferably contained in the catalyst particle 5. In addition, 80 atomic percent or less of one element of Fe, Co, and Ni is preferably contained in the catalyst particle 5. More preferably, with respect to the Pd contained in the catalyst particle 5, 20 atomic percent or more and 80 atomic percent or less of one element of Fe, Co, and Ni is contained in the catalyst particle 5.

When the ratio of one element of Fe, Co, and Ni contained in the catalyst particle 5 is less than 20 atomic percent, compared to the catalyst particle 5 composed of 100% of Pd, the voltage required for obtaining a sufficient amount (such as 1 μA) of electron emission cannot be remarkably decreased. In addition, when the ratio is more than 80 atomic percent, the temperature required for growing the carbon fiber 6 is rapidly increased and becomes substantially equivalent to that obtained when the catalyst particle 5 is composed of 100% of Co. From the points described above, the ratio of one element of Fe, Co, and Ni contained in the catalyst particle 5 is preferably in the range of 20 to 80 atomic percent.

(Step 3)

Next, a step of growing the carbon fiber 6 on the substrate 1 using the catalyst particle 5 will be described.

In particular, the carbon fiber 6 can be manufactured by a CVD (chemical vapor deposition) method in which a raw material gas for the carbon fiber is decomposed. As the CVD method, for example, a plasma CVD method or a thermal CVD method may be used. A thermal CVD method is particularly preferable since manufacturing can be simply performed. In addition, in consideration of the uniformity and electron emission performance of the carbon fibers, a low pressure thermal CVD method is preferably used.

As the raw material gas for the carbon fiber, a gas containing carbon may be used.

As the gas containing carbon used in the present invention, for example, a hydrocarbon gas, such as acetylene, ethylene, methane, propane, or propylene is preferably used. Vapor of an organic solvent, such as ethanol or acetone, may also be used. In addition, a mixed gas of the above hydrocarbon gas and a hydrogen gas is more preferably used. When the mixed gas of the hydrocarbon gas and a hydrogen gas is used, even if the catalyst particle 5 formed in the step 2 is disposed on the substrate 1 in the form of a metal compound of the first and/or the second catalyst material, the metal compound is reduced by the hydrogen gas contained in the mixed gas. Accordingly, without performing any particular reducing treatment as described above, the carbon fiber 6 may be grown, and hence the mixed gas described above is preferably used.

In addition, the carbon fiber 6 may contain the catalyst particle 5 at one end portion (in the vicinity of the front end portion), which is not fixed to the substrate 1, of the two end portions of the carbon fiber, or the carbon fiber 6 may contain the catalyst particle 5 at a place between the two end portions described above. In addition, the case may also occur in which the catalyst particle 5 remains on the substrate 1 (or the electrode 2), and one end of the carbon fiber is connected to the catalyst particle 5. It is preferable that the catalyst particle 5 be not exposed and be enclosed in the carbon fiber.

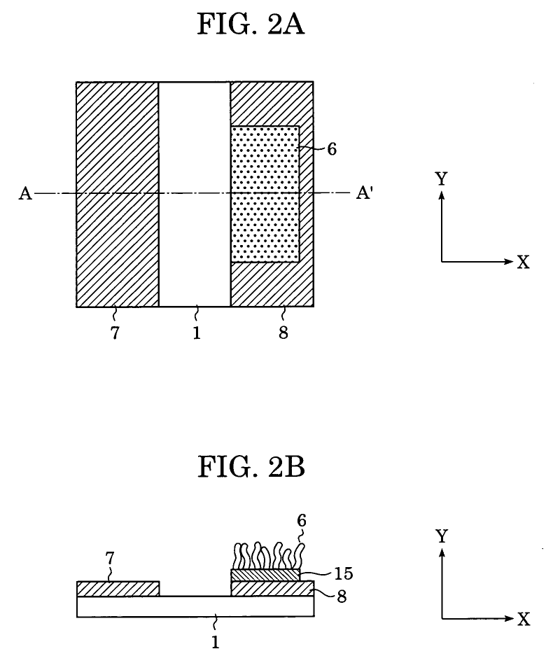

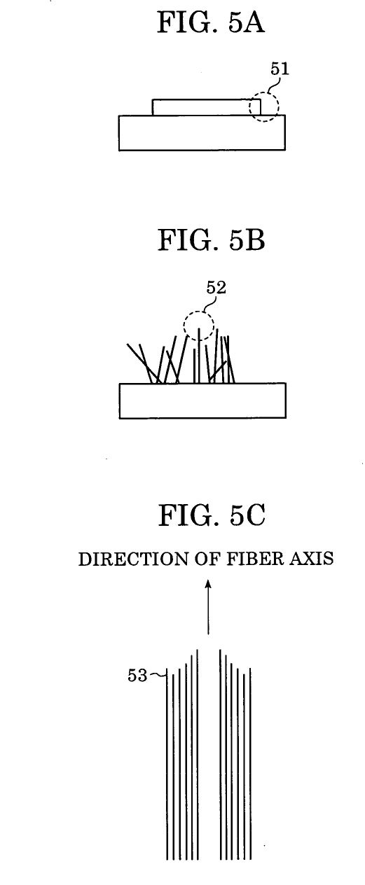

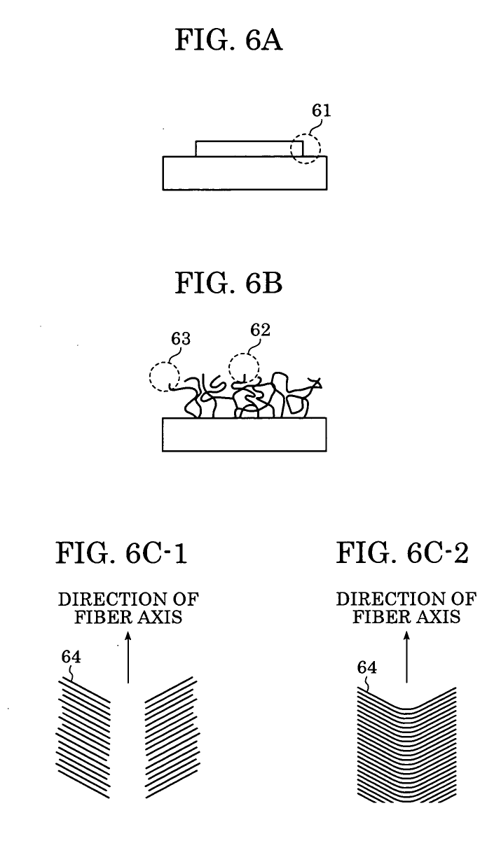

The carbon fibers 6 formed in this step are schematically shown in FIGS. 5A to 6C-2. FIGS. 5A and 6A each show the structure observed using an optical microscope or the like (up to a magnification of 1,000). FIGS. 5B and 6B each show the structure observed using a scanning electron microscope (SEM) or the like (up to a magnification of 30,000) and are enlarged views of parts (51 and 61) shown in FIGS. 5A and 6A, respectively. FIGS. 5C, 6C-1, and 6C-2 each show the structure of carbon (graphene) observed using a transmission electron microscope (TEM) or the like (up to a magnification of 1,000,000). FIG. 5C is an enlarged view of a part (52) shown in FIG. 5B, FIG. 6C-1 is an enlarged view of a part (62) shown in FIG. 6B, and FIG. 6C-2 is an enlarged view of another part (63) shown in FIG. 6B.

In this case, the graphite is composed of stacked carbon planes with an ideal space of approximately 3.354 Å provided therebetween. Each of the carbon planes is composed of a plurality of hexagons arranged side-by-side, each of the hexagons is made of 6 carbon atoms bonded to each other. The hexagon includes three covalent bonds, each of which is called the sp² hybrid orbit. This one carbon plane described above is called “graphene” or a “graphene sheet”.

As shown in FIG. 5C, a carbon fiber composed of a cylindrical (tubular) graphene 53 is called a “carbon nanotube”. A carbon fiber composed of multiple cylindrical (tubular) graphenes is called a “multiwall carbon nanotube”. In addition, a carbon nanotube made of single tubular graphene 53 is called a “single wall carbon nanotube”. In particular, a carbon nanotube having an open end portion has the lowest threshold value of an electric field required for electron emission. In addition, some of the multiwall carbon nanotubes have a bamboo-joint like structure in the hollow portion thereof, and most of those tubes have an outermost graphene sheet having an angle of 0° with respect to the direction of the fiber axis (that is, the longitudinal axis of the graphene sheet is parallel to the longitudinal axis of the carbon fiber). The structure as described above is also categorized as a carbon nanotube. In the carbon nanotubes as described above, the direction of the longitudinal fiber axis and the longitudinal axis of the graphene (or the carbon plane) formed at the outermost place of the tube are approximately parallel to each other (that is, an angle formed between the fiber axis (longitudinal direction of the fiber) and the longitudinal axis of the graphene is approximately 0°). The inside of the carbon nanotube is typically hollow, but some other material may be introduced into the hollow part.

Next, each of the carbon fibers schematically shown in FIGS. 6C-1 and 6C-2 is composed of a plurality of graphenes 64 which are stacked with respect to each other in the direction of the fiber axis. The carbon fiber having this structure is called a “graphite nanofiber” in some cases and is to be discriminated from the carbon nanotube described above. That is, in the carbon nanotube described above and shown in FIG. 5C, the c crystallographic axis (the direction in which graphenes are laminated with respect to each other, or the direction perpendicular to the surface of the graphene (perpendicular to the carbon plane)) is substantially perpendicular to the direction of the fiber axis (longitudinal direction of the fiber); however, in the graphite nanofiber, the c crystallographic axis (the direction in which graphenes are stacked with respect to each other, or the direction perpendicular to the surface of the graphene) is not perpendicular to the direction of the fiber axis (longitudinal direction of the fiber) and is typically parallel thereto.

When the angle formed between the longitudinal fiber axis and the surface of the graphene is approximately 90°, the fiber is called a “platelet type”. In other words, the structure is formed in which many graphene sheets are stacked to each other as if playing cards are piled up.

On the other hand, as shown in FIGS. 6C-1 and 6C-2, when the angle formed between the fiber axis and the surface of the graphene 64 is less than 90° and more than 0°, the fiber is called a “herringbone type”. A carbon fiber having a stacked bottomless-cup-shaped graphene sheets can be also categorized to the “herringbone type structure”. In addition, a carbon fiber having stacked opened-book-shaped graphene sheets (stacked V-shaped graphene sheets) can be also categorized as the “herringbone type structure”.

The vicinity of the center of the fiber axis of the herringbone type structure may be hollow, or amorphous carbon may be filled therein in some cases. In the case in which the amorphous carbon is filled, clear spots or contrast images caused by the crystal lattice are not observed by analysis of an electron beam diffraction image using a TEM or the like, and for example, a broad ring pattern may only be observed.

FIGS. 5A to 6C-2 are schematic views showing the cases in which carbon fibers having inferior linearity are grown. The carbon fibers manufactured by the manufacturing method of the present invention do not always have inferior linearity as described above, and carbon fibers having superior linearity can also be obtained.

The carbon nanotubes and graphite nanofibers are preferably used for electron-emitting devices in view of the electron emission properties thereof. In particular, since obtaining a larger emission current than that of the carbon nanotubes, the graphite nanofibers are preferably used. However, in addition to the carbon nanotubes and the graphite nanofibers, the present invention can be applied to other carbon fibers formed by a thermal CVD method.

Carbon nanotubes and graphite nanofibers can be selectively formed by choosing the type of catalyst and/or the decomposition temperature of a raw material gas used for carbon fibers. Even when the same type of catalyst is used, two types of carbon fibers having different structures can be selectively formed by controlling the temperature. In addition, a carbon fiber having one of the above two structures can also be formed.

The two types of carbon fibers having different structures described above both have an electron emission threshold of approximately 1 to 10 V/μm, and have preferable properties as an electron emission material. When carbon fibers are used for forming electron-emitting devices, each electron-emitting device preferably contains a plurality of carbon fibers. In addition, as the electron emission material, graphite nanofiber is more preferably used as the carbon fiber. The reason for this is that in an electron-emitting device in which a plurality of graphite nanofibers is used as the electron emission material (an electron emission film including a plurality of graphite nanofibers), a large electron emission current density can be secured as compared to that obtained when carbon nanotubes are used.

Unlike the carbon nanotubes and the like, since the graphite nanofibers have fine irregularities on the surface (the outer peripheral surface of the fiber), concentration of the electric field is likely to occur, and hence it is believed that electrons are likely to be emitted. In addition, since the structure is formed in which graphene sheets extend from the central axis of the fiber to the periphery (surface) thereof, it is believed that electron emission is likely to occur.

On the other hand, as for the carbon nanotubes described above and shown in FIG. 5C, it is believed that since the outer peripheral surface of the fiber basically corresponds to the outermost graphene surface from which the c crystallographic perpendicularly extends, the carbon nanotube is chemically inactive, and that since irregularities described above are not present thereon, unlike the graphite nanofibers, no electron emission occurs from the outer peripheral surface of the tube. Hence, as the carbon fibers, it is believed that the graphite nanofibers are preferably used for an electron-emitting device.

By the steps described above, the carbon fibers can be formed.

Next, an electron-emitting device using the carbon fibers manufactured in accordance with the present invention will be described.

In the present invention, for forming an electron-emitting device, a plurality of carbon fibers formed in the above step 3 is connected to a cathode so as to form the electron-emitting device. In this step, when the electrode (conductive layer) 2 formed on the substrate 1 described above is used as the cathode, the carbon fibers can be directly formed on the cathode; hence, as a result, the manufacturing process can be preferably simplified.

However, the electron-emitting device can also be formed by collecting many carbon fibers which are separately manufactured by the method for manufacturing carbon fibers, according to the present invention, and disposing a plurality of carbon fibers selected from the above collected many carbon fibers on the cathode.

In the case described above, for example, a paste containing a plurality of carbon fibers is prepared by mixing the collected carbon fibers with a printing paste, and this paste thus prepared is applied onto the cathode by a printing method or the like, followed by baking, thereby fixing the plurality of carbon fibers on the cathode. In addition, the paste described above may contain a conductive material and/or an adhesive, such as a glass frit, whenever necessary.

In addition, when an electrode (extraction electrode: gate electrode or anode) for drawing electrons from the carbon fibers disposed on the cathode is provided so as to face the carbon fibers, the electron-emitting apparatus (electron-emitting apparatus having a so-called diode structure) can be obtained.

Furthermore, when a light-emitting member, such as a fluorescent body (phosphor), which emits light when being irradiated with electrons emitted from the carbon fibers, is disposed on the extraction electrode (gate electrode or anode), a light-emitting apparatus, such as a lamp, can be formed.

In addition, when an apparatus having a triode structure is formed (building on an electron-emitting device having a diode structure), a gate electrode is disposed at a position apart from the cathode (cathode electrode) having the carbon fibers 6 provided thereon to form an electron-emitting device having a diode structure, and an anode (anode electrode) is disposed so as to face this electron-emitting device, thereby forming an electron-emitting apparatus having a triode structure.

In addition, when a transparent substrate having the anode and the light-emitting member is disposed so as to face a substrate having a plurality of electron-emitting devices using the carbon fibers 6 provided thereon, an image display device, such as a display panel, can also be formed.

In the electron-emitting device, the light-emitting apparatus, and the image display device using the carbon fibers of the present invention, stable electron emission can be achieved without maintaining the inside thereof under an ultra high vacuum condition such as that in a related electron-emitting device, and electron emission can be effected with a low strength electric field. Hence, highly reliable devices can be very easily manufactured.

Next, an electron-emitting device will be described in detail with reference to FIGS. 2A and 2B, the element using the carbon fibers 6 obtained by the present invention as an electron emission member. In this embodiment, a lateral-type electron-emitting device having a diode structure will be described by way of example.

FIG. 2A is a schematic plan view showing a lateral-type electron-emitting device having a diode structure, and FIG. 2B is a schematic cross-sectional view of the above electron-emitting device taken along the line A-A′ in FIG. 2A.

In FIGS. 1A to 1F, 2A and 2B, reference numeral 1 denotes an insulating substrate, numeral 7 denotes a control electrode (which can also function as an extraction electrode, and may be used as a gate electrode in some cases), numeral 8 denotes a cathode, numeral 14 denotes a resist pattern, numeral 15 denotes a conductive material layer, and numeral 6 denotes carbon fibers. Alloy catalyst particles 5 (not shown in FIGS. 2A and 2B) are also provided on the cathode 8. In this case, the conductive material layer 15 may not be always necessary.

One example of a manufacturing method of the electron-emitting device shown in FIGS. 2A and 2B will be described with reference to FIGS. 1A to 1F. In this case, the method for manufacturing carbon fibers is exactly the same as that described above, and one example thereof will be described.

(Step A)

After the substrate 1 is sufficiently washed, in order to form the extraction electrode 7 and the cathode 8, an electrode layer (not shown) having a thickness of 500 nm is formed on the entire substrate 1 by sputtering or the like.

Next, after a resist pattern is formed using a positive type photoresist (not shown) in a photolithographic step,. the electrode layer is processed by dry etching with an Ar gas using the patterned photoresist as a mask, so that the extraction electrode 7 and the cathode 8 are formed with an electrode gap (width of the space) of 5 μm provided therebetween (FIG. 1A).

As the substrate 1, for example, quartz glass, soda lime glass, low alkaline glass having an alkaline component lower than that of soda lime glass, or non-alkaline glass may be used.

In addition, a patterning of a thin film or a resist performed by the steps including photolithography, film formation, lift-off, etching, and the like will be simply called patterning.

(Step B)

In a photolithographic step, the resist pattern 14 used in a subsequent lift-off step is formed using a negative type photoresist (FIG. 1B).

Next, the conductive material layer 15 is formed. Onto the layer described above, a dispersion liquid of the particles 3 containing the second catalyst material (such as Pd) described above is then applied, for example, by spin coating. Subsequently, heating is performed, followed by reducing treatment, thereby forming the catalyst particles 3 of Pd or the like (FIG. 1C).

In this case, in order to suppress reaction between the cathode 8 and the catalyst particles 5, which will be described later, the conductive material layer 15 is provided. As a preferable material for the conductive material layer 15 as described above, a transition metal nitride may be used. As the transition metal nitride, for example, TiN, ZrN, TaN, HfN, VN, and CrN may be mentioned. In addition, an oxide such as TiOx may also be used when it has a small thickness. In addition, when the conductive material layer 15 as described above is disposed between the cathode 8 and the catalyst particles 5, the range of selection of a material for the cathode 8 can be increased.

(Step C)

Next, as described above, the substrate 1 is immersed in an electrolytic plating bath of the first catalyst material (such as Co), so that the first catalyst material 4 is precipitated on the individual particles 3 containing the second catalyst material (FIG. 1D).

As another method, a method may be performed in which after a solution of a first metal organic compound containing Fe, Co, or Ni is spin coated, baking is performed at 350° C., followed by reduction, so that the first catalyst material is disposed on the particles 3 containing the second catalyst material. Accordingly, laminated bodies formed of the particles 3 containing the second catalyst material and the first catalyst material 4 are formed (FIG. 1D′).

Alternatively, the first catalyst material 4 such as Fe, Co, or Ni may be disposed on the particles 3 containing the second catalyst material, such as Pd, by sputtering or the like.

In the case described above, the particles 3 containing the second catalyst material and the first catalyst material 4 may be disposed in the order opposite to that described above. That is, after the first catalyst material 4 such as Fe, Co, and Ni is first disposed on the electrode 2, the particles 3 containing the second catalyst material may then be disposed thereon so as to form laminated bodies (laminated members).

(Step D)

By using a remover for the resist pattern 14, a part of the conductive material layer 15 and some of the laminated bodies formed of the particles 3 containing the second catalyst material and the first catalyst material 4 which are located on the resist pattern 14 are removed by a lift-off technique together with the resist pattern 14. By this step, in desired regions, the conductive material layer 15, the particles 3 containing the second catalyst material, and the first catalyst material 4 are allowed to remain (FIG. 1E).

(Step E)

Next, by heating the substrate 1 in a gas stream containing a hydrocarbon gas and hydrogen, a thermal CVD process is performed. In this case, in the heating, reduction of the first catalyst material and the second catalyst material and reaction (alloying reaction) therebetween are carried out, and in addition, many carbon fibers 6 are also grown on the cathode 8 (FIG. 1F).

Alternatively, before the carbon fibers are grown, the reaction (alloying reaction) between the first and the second catalyst materials and/or the reduction of the first and the second catalyst materials can be separately performed.

By the steps described above, the lateral-type electron-emitting device can be formed.

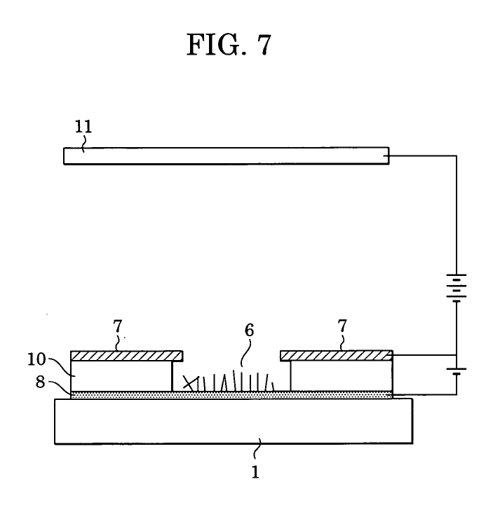

With reference to the example described above, the lateral-type electron-emitting device has been described; however, the present invention can also be applied to a vertical-type electron-emitting device as show in FIG. 7. In FIG. 7, reference numeral 1 denotes a substrate, numeral 8 denotes a cathode, numeral 7 denotes a control electrode (may be used as a gate electrode in some cases), numeral 6 denotes carbon fibers, numeral 10 denotes an insulating layer, and numeral 11 denotes an anode. Also in the structure shown in FIG. 7, a method for manufacturing carbon fibers 6 is basically the same as described above.

Since manufacturing is not complicated, and high speed driving can be performed due to a small capacity component in driving, the lateral-type electron-emitting device has a preferable structure as compared to that of the vertical electron-emitting device. On the other hand, the vertical electron emission is preferable since the spread of emitted electron beams can be decreased as compared to that of the lateral-type electron-emitting device.

The term “lateral-type electron-emitting device” denotes an electron-emitting device having the structure in which an electric field for driving electron emission is formed in a direction substantially parallel to the surface of the substrate 1, and in which by this electric field, electrons are extracted from the carbon fibers 6. On the other hand, the term “vertical electron-emitting device” denotes an electron-emitting device having the structure in which an electric field is formed in a direction substantially perpendicular to the surface of the substrate 1, and in which by this electric field, electrons are extracted from the carbon fibers 6.

In addition, each of the electron-emitting devices shown in FIGS. 2A, 2B, and 7 includes the cathode 8 and the control electrode 7; however, since the carbon fibers 6 can emit electrons at a low electric field strength, the present invention can be applied to an electron-emitting device having the structure in which the control electrode 7 shown in FIGS. 2A and 2B is not provided (the structure in which the control electrode 7 and the insulating layer 10 shown in FIG. 7 are not provided).

That is, the present invention can also be applied to an electron-emitting device formed of the cathode 8 provided on the substrate 1 and the carbon fibers 6 disposed on the cathode 8 (an electron-emitting apparatus having a diode (two terminal) structure when the anode 11 is included as shown in FIG. 7).

In addition, in the electron-emitting apparatus having a triode structure as shown in FIG. 7, the control electrode 7 may function as a so-called gate electrode (electrode for extracting electrons from the carbon fibers 6) in some cases. However, since the carbon fibers 6 can emit electrons at a low electric field strength, the anode 11 may extract electrons from the carbon fibers 6, and the control electrode 7 may be used in some cases for modulation of the amount of electrons emitted from the carbon fibers 6, shutdown of the electron emission, or shaping, such as focusing, of emitted electron beams.

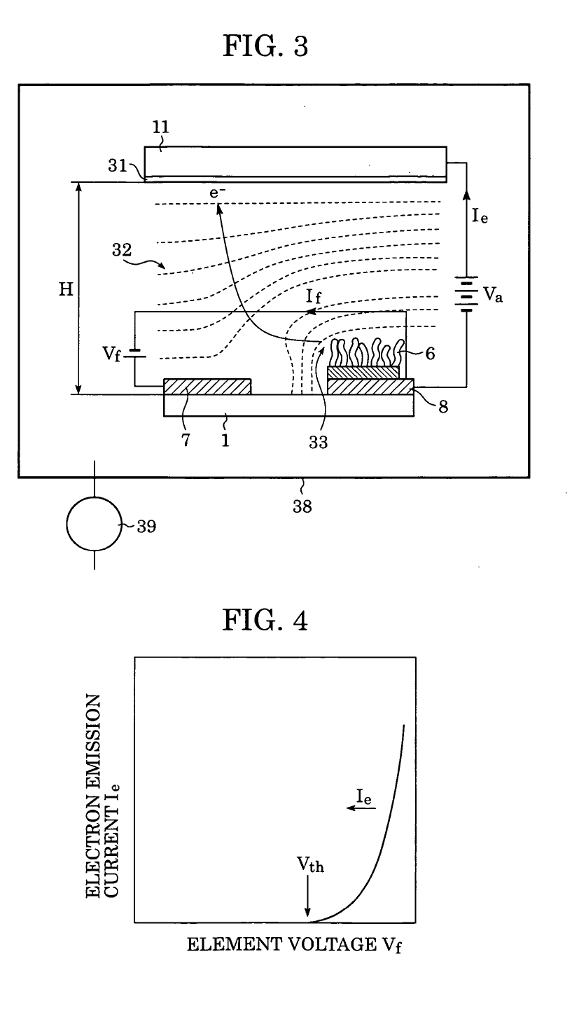

Next, with reference to the electron-emitting device using the carbon fibers, shown in FIGS. 2A and 2B, the electron emission properties will be described in conjunction with FIGS. 3 and 4.

In order to measure the electron emission properties, first, the electron-emitting device is placed in a vacuum device 38 as shown in FIG. 3, and the gas inside of the device 38 is sufficiently evacuated by a vacuum pump 39 to a pressure of approximately 10⁻⁴ Pa. Subsequently, the anode 11 is provided at a height H of several millimeters above the substrate 1, and by using a high voltage source as shown in FIG. 3, a voltage Va is applied to the anode 11 so that the potential thereof becomes higher than that of electron-emitting device by several kilovolts.

In this example, a phosphor 31 coated with a conductive film is provided for the anode 11.

A pulse voltage having a height of several tens of volts is applied as a drive voltage V_{f} to the electron-emitting device, and in accordance with this pulse voltage, a device current I_{f} flowing between the electrodes 8 and 7 and an electron emission current Iₑ flowing into the anode 11 are measured.

In FIG. 3, equi-potential lines 32 are shown by dotted lines which are formed in the vicinity of the electron-emitting device when the voltage is applied to each electrode as described above. A portion 33 at which the electric field is most concentrated is estimated to be located at some of the carbon fibers 6 located at a position closest to the anode 11 and close to the gap (space) between the cathode 8 and the control electrode 7.

It is also estimated that electrons are emitted from the front ends of the carbon fibers 6 and/or the vicinity thereof, which are located in the vicinity of the upper portion of the carbon fibers 6 at which the electric field is concentrated.

In addition, the Iₑ properties of the electron-emitting device are as shown in FIG. 4. That is, the electron-emitting device of the present invention has a clear voltage threshold required for electron emission. In FIG. 4, the transverse axis indicates the drive voltage (device voltage) V_{f} applied between the cathode 8 and the extraction electrode 7, and the longitudinal axis indicates the emission current Iₑ flowing into the anode 11 in accordance with the application of the drive voltage. The properties described above are the same as those of the vertical-type electron-emitting device shown in FIG. 7.

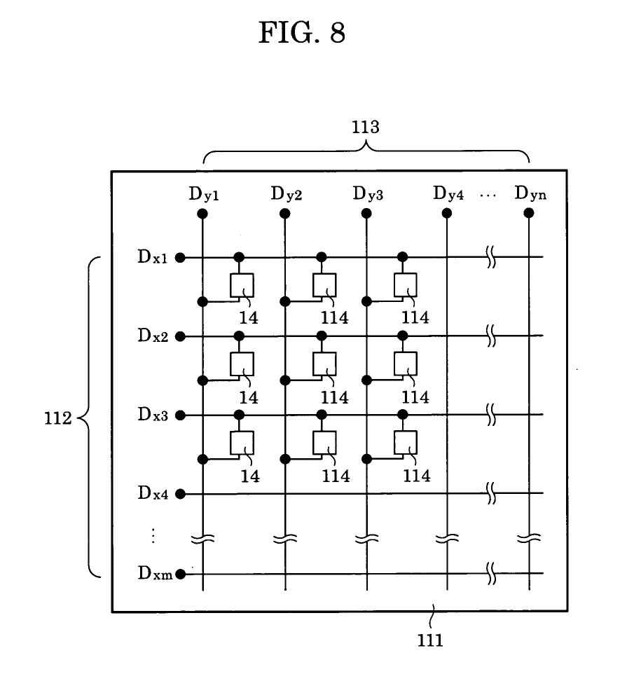

Next, one example of an electron source having a plurality of the above lateral-type electron-emitting devices will be described with reference to FIG. 8.

In FIG. 8, reference numerals 111, 112, 113, and 114 respectively indicate a substrate provided with an electron source, X-direction wirings, Y-direction wirings, and an electron-emitting device of the present invention.

In FIG. 8, m X-direction wirings 112 are denoted by Dₓ₁, Dₓ₂ . . . and Dₓₘ. The material, thickness, and width of the wirings may be determined according to need. In addition, n Y-direction wirings 113 are denoted by D_{y1}, D_{y2} . . . and D_{yn}, and are formed in the same manner as that of the X-direction wirings 112. Between the m X-direction wirings 112 and the n Y-direction wirings 113, an interlayer insulating layer (not shown) is provided, so that they are electrically isolated from each other (in which m and n are both positive integers).

The end of any X-direction wiring 112 and that of any Y-direction wiring 113 may also function as a terminal to be connected to a drive circuit.

The cathode (not shown) forming the electron-emitting device 114 obtained in accordance with the manufacturing method of the present invention is electrically connected to one of the X-direction wirings 112 and the Y-direction wirings 113, and the control electrode is electrically connected to the other of the X-direction wirings and the Y-direction wirings.

To the X-direction wirings 112, for example, scanning signal application means (not shown) for applying a scanning signal is connected. On the other hand, to the Y-direction wirings 113, for example, modulation signal generation means (not shown) is connected which modulates the amount of electrons emitted in response to a modulation signal synchronized with the scanning signal. The drive voltage V_{f} applied to each electron-emitting device 114 is supplied as the difference in voltage between the applied scanning signal and the applied modulation signal. By the structure as described above, one particular electron-emitting device 114 can be selected and can be independently driven.

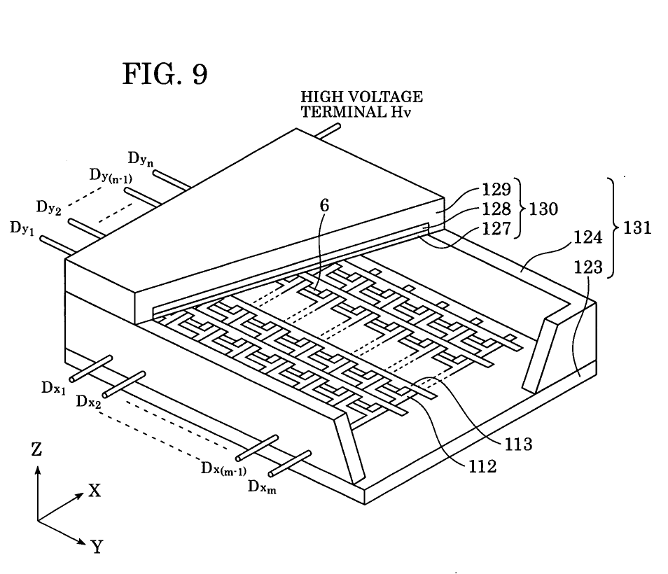

Next, one example of an image display device formed of the above electron source having a matrix arrangement will be described with reference to FIG. 9.

In FIG. 9, reference numeral 123 indicates a substrate (rear plate) having the electron source, and reference numeral 130 indicates a face plate in which a fluorescent film 128 and a conductive film (metal back) 127 are formed inside a glass substrate 129. Reference numeral 124 indicates a support frame, and this support frame 124 is connected to the rear plate 123 and the face plate 130. Reference numeral 131 denotes an envelope 131, also called a display panel, and this envelope 131 is formed when the face plate 130, the support frame 124, and the rear plate 123 are bonded to each other for sealing.

Reference numeral 6 indicates carbon fibers obtained by the manufacturing method of the present invention. Reference numerals 112 and 113 indicate an X-direction wiring and a Y-direction wiring, respectively.

An adhesive, such as a frit glass or indium, is applied to the rear plate 123, the support frame 124, and the face plate 130, at individual bonding portions and are then heated in the air, nitrogen, or a vacuum environment, so that the bonding (joining) therebetween can be achieved for sealing. In this case, the conductive film 127 described above is a member corresponding to the anode 11 described with reference to FIG. 3 or 7.

In the case where the envelope 131 is formed by the bonding in the air or in a nitrogen environment, after evacuation is performed using an exhaust pipe (not shown) until the inside pressure reaches a desired degree of vacuum (such as approximately 1.3×10⁻⁵ Pa), the exhaust pipe is sealed, and hence the envelope 131 is sealed so that the inside thereof is maintained under a vacuum condition. In addition, when the bonding is performed under a vacuum condition, without using the exhaust pipe, the bonding and the sealing can be simultaneously achieved, and as a result, the envelope 131 can be obtained in which the inside thereof is easily maintained under a vacuum condition.

In addition, before or after the sealing is performed, a getter (not shown) disposed inside the envelope 131 may be activated in some cases. When the bonding is performed in a vacuum environment as described above, before or after the bonding is performed, a getter (not shown) disposed inside the envelope 131 is activated. By the above procedure, the degree of vacuum inside the envelope 131 after the sealing can be maintained.

The envelope 131 is formed of the face plate 130, the support frame 124, and the rear plate 123, as described above. In addition, when a support member (not shown) which is called a spacer is provided between the face plate 130 and the rear plate 123, the envelope 131 can be formed to have a sufficient strength against the atmospheric pressure.

In order to further improve the conductivity of the fluorescent film 128 of the face plate 130, a transparent electrode (not shown) formed, for example, of ITO (indium-tin oxide) may be provided between the fluorescent film 128 and the glass substrate 129.

When a voltage is applied to the individual electron-emitting devices disposed in the envelope 131 through respective terminals Dox1 to Doxm connected to the X-direction wirings and respective terminals Doy1 to Doyn connected to the Y-direction wirings, electron emission can be performed by a desired electron-emitting device. In this case, a voltage of 5 to 30 kV or preferably 10 to 20 kV is applied to the metal back 127 through a high voltage terminal Hv. By this application, electrons emitted from the selected electron-emitting device pass through the metal back 127 and then collide against the fluorescent film 128. The fluorescent film 128 thus excited emits light, so that an image is displayed. In this structure, the distance between the face plate and the rear plate is set in the range of 1 to 10 mm and preferably in the range of 1 to 5 mm.

In the structure described above, the details, such as the materials of the individual members, are not limited to those described above, and in consideration of various purposes, they may be optionally modified or changed.

In addition, by using the display panel corresponding to the above envelope 131 of the present invention, which was described with reference to FIG. 9, an information display reproduction apparatus can be formed.

In particular, the structure is formed in which a receiving device receives television broadcasting signals or the like, a tuner tunes to the received signals and outputs at least one of an image signal, a character signal, and an audio signal contained in the tuned signals to the display panel 131, and the display panel 131 displays and/or reproduces the above information. By the structure described above, an information display reproduction. apparatus, such as a television, can be formed. When the broadcasting signals are encoded, of course, the information display reproduction apparatus of the present invention may include a decoder. In addition, audio signals are output to audio reproduction means, such as a speaker, which is separately provided and are then reproduced in synchronism with the image signal or the character signal displayed on the display panel 131.

In addition, for example, a method for outputting an image signal or a character signal to the display panel 131 for displaying or reproducing the information on a screen may be performed as described below.

First, from a received image signal and character signal, image signals are generated for respective pixels of the display panel 131. Then, the generated image signals are input to a drive circuit of the display panel 131. Subsequently, in accordance with the image signals input to the drive circuit, voltages applied from the drive circuit to the individual electron-emitting devices in the display panel are controlled, so that the image is displayed.

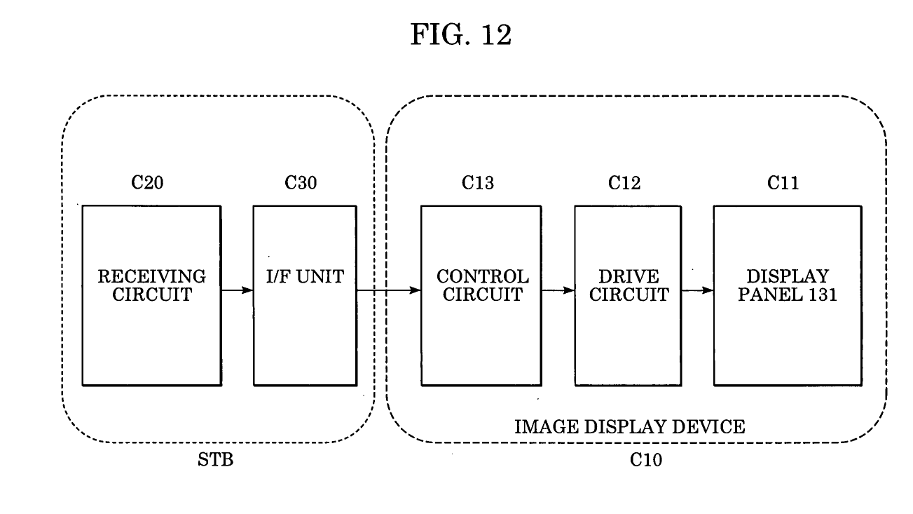

FIG. 12 is a block diagram of a television apparatus according to the present invention. A receiving circuit C20 is composed of a tuner, a decoder, and the like, and after receiving television signals of satellite broadcasting, ground based broadcasting, or the like, or signals of data broadcasting through networks, the receiving circuit C20 outputs decoded picture data to an I/F portion (interface portion) C30. The I/F portion C30 converts the picture data into a display format of the display device and then outputs image data to an image display device C10 that includes the display panel 131 (C11), a drive circuit C12, and a control circuit C13. The control circuit C13 performs image processing, such as correction treatment on the image data from the I/F portion C30 so that the input image data conforms to the requirements of the display panel and also outputs the image data and various control signals to the drive circuit C12. The drive circuit C12 outputs drive signals to the individual wirings (see through terminals Dox1 to Doxm, and Doy1 to Doyn in FIG. 9), so that the television picture is displayed. The receiving circuit C20 and the I/F portion C30 may be placed in a case of a set top box (STB), which is different and separate from that for the image display device C10, or may be placed in the same case.

In addition, the I/F portion C30 may be formed to be connected with an image recording device or an image output device such as a printer, a digital video camera, a digital camera, a hard disc drive (HDD), and a digital video disc (DVD). According to the structure described above, an image recorded in the image recording device can be displayed on the display panel 131, and in addition, an information display reproduction apparatus (or television) can be formed which can process the image displayed on the display panel 131 whenever necessary and which enables the image output device to output the above image.

The structure of the image display device described above is one example of the image display device to which the present invention can be applied, and the structure may be variously modified without departing from the technical scope of the present invention. In addition, the image display device of the present invention may also be used as display devices for TV conference systems, computers, and the like.

In addition, the present invention may be variously modified and changed without departing from the technical scope of the present invention.

### EXAMPLES

Hereinafter, examples of the present invention will be described in detail.

### Example 1

In this example, in accordance with the steps shown in FIGS. 1A to 1F, an electron-emitting device was manufactured.

(Step 1)

First, as the substrate 1, a quartz substrate was prepared and was sufficiently washed. Subsequently, in order to form the gate electrode 7 and the cathode 8, over the entire substrate 1, a Ti layer (not shown) having a thickness of 5 nm was deposited by using a sputtering method, followed by deposition of a Pt layer having a thickness of 100 nm.

Next, in a photolithographic step, a resist pattern was formed using a positive type photoresist (not shown).

Subsequently, by using the photoresist thus patterned as a mask, the Pt layer and the Ti layer were dry-etched using an Ar gas so that the extraction electrode 7 and the cathode 8 were formed with an electrode gap (width between the electrodes) of 5 μm (FIG. 1A) provided therebetween.

(Step 2)

In a photolithographic step, the resist pattern 14 for lift-off in a subsequent step was formed using a negative type photoresist (FIG. 1B).

(Step 3)

Next, as the conductive material layer, the TiN layer 15 (corresponding to the conductive material layer 15) was formed. Subsequently, an ethanol dispersion liquid (content of Pd: 0.2 mmol/l, particle diameter: approximately 10 nm, a dispersing agent, PVP (polyvinyl pyrrolidone), dispersion medium (solvent): ethanol) of palladium particles, which were the particles containing the second catalyst material, was further applied to the TiN layer 15 by spin coating and was then fired at 350° C. for 10 minutes in the air, and reduction treatment was performed at 600° C. in a hydrogen stream. By the above steps, many Pd particles 3 were disposed on the TiN layer 15 (FIG. 1C). In this case, the spaces provided between the Pd particles were 100 to 1,000 nm, and the particle diameter thereof was 10 nm.

(Step 4)

The substrate 1 processed by the steps 1 to 3 was immersed in an electrolytic plating Co bath 18 (FIG. 1D). The composition, the temperature, and the pH of the electrolytic plating Co bath were as follows.

| Cobalt chloride (hexahydrate): | 11.9 g/l |
|---|---|
| Hydrazine hydrochloride: | 68.51 g/l |
| Sodium tartrate (dihydrate): | 92.03 g/l |
| Temperature: | 80° C. |
| pH | 12 |

By the treatment described above, the Co films 4 were provided only on the Pd particles 3 so as to enclose the respective Pd particles 3. Next, after baking was performed at 350° C. for 10 minutes in the air, reduction was performed at 600° C. in a hydrogen stream. The catalyst particles 5 obtained in this step were disposed with a space of approximately 30 nm provided therebetween and were not substantially shifted from the positions on which the Pd particles 3 were provided in the step 3.

In addition, when catalyst particles were analyzed by an X-ray analysis, which were obtained by the steps of forming the Pd particles 3 on the TiN layer with a smaller space (at higher distribution density) therebetween than that described in the above step 3, and performing the same step as the above step 4, a peak of an alloy of Pd and Co was observed. In addition, with respect to the Pd contained in the alloy catalyst particle, the ratio of the Co contained therein was approximately 50%. Hence, the particles 5 formed in the step 4 of this example were also estimated to be alloy particles of Pd and Co.

(Step 5)

By using a remover for the resist pattern 14 formed in the step 2, a part of the conductive material layer 15 and some of the catalyst particles 5 on the resist pattern 14 were processed by a lift-off technique together therewith, so that the conductive material layer 15 and the catalyst particles 5 are allowed to remain in a desired region (FIG. 1E).

(Step 6)

Subsequently, heating treatment was performed for the substrate 1 in an acetylene stream, thereby forming many carbon fibers 6 connected to the cathode 8 (FIG. 1F).

The lateral-type electron-emitting device thus formed was placed in the vacuum device 38 shown in FIG. 3, and the inside thereof was sufficiently evacuated by the vacuum pump 39 until the pressure reached 2×10⁻⁵ Pa. Subsequently, to the anode 11 disposed above the electron-emitting device at a height H of 2 mm therefrom, a voltage Va of 10 kV was applied as a potential difference (voltage) from that of the cathode 8. Furthermore, a pulse voltage, which was a drive voltage V_{f} of 20 V, was applied between the cathode 8 and the gate electrode 7, and the device current I_{f} flowing between the cathode 8 and the gate electrode 7 and the electron emission current Iₑ flowing into the anode were measured.

The properties of I_{f} and Iₑ thus measured were as shown in FIG. 4. That is, Iₑ rapidly increased at an approximately half of the applied drive voltage V_{f}, i.e., 10V and when V_{f} was 20 V, approximately 1.1 μA was measured as the electron emission current Iₑ. On the other hand, although the properties of I_{f} were similar to those of Iₑ, the value of I_{f} was approximately one tenth or less of that of Iₑ.

In the electron-emitting device formed in this example, the carbon fibers were disposed on the cathode 8 with appropriate spaces provided therebetween. Hence, it is believed that the electric field effectively worked on the carbon fibers, and that superior electron emission properties were obtained.

In addition, the carbon fibers formed in this example were the platelet-type graphite nanofibers described above.

### Example 2

In this example, an electron-emitting device was formed in the same manner as that in example 1 except that the step 4 of example 1 was performed as described below. Hence, hereinafter, only the step 4 will be described.

(Step 4)

Co, which was the first catalyst material, was provided on the Pd particles 3 by sputtering to have a thickness of 1.5 nm (FIG. 1D′). Subsequently, after baking was performed at 350° C. for 10 minutes in the air, reduction was performed at 600° C. in a hydrogen stream. The catalyst particles 5 obtained in this step were disposed with spaces of approximately 100 to 1,000 nm provided therebetween and were not substantially shifted from the positions on which the Pd particles 3 were provided in the step 3.

In addition, when catalyst particles were analyzed by an X-ray analysis, which were obtained by the steps of forming the Pd particles 3 on the TiN layer with a smaller space (at higher distribution density) therebetween than that described in the above step 3, and performing the same step as the above step 4, a peak of an alloy of Pd and Co was observed. In addition, the ratio of the Co contained in the alloy catalyst particle was approximately 40%. Hence, the particles 5 formed in the step 4 of this example were also estimated to be alloy particles of Pd and Co.

When the electron emission properties of the electron-emitting device obtained in this example were measured in the same manner as that in example 1, the properties of I_{f} and Iₑ were as shown in FIG. 4. That is, Iₑ was rapidly increased at an approximately half of the applied drive voltage, i.e., 10V, and when V_{f} was 20 V, approximately 0.9 μA was measured as the electron emission current Iₑ. On the other hand, although the properties of I_{f} were similar to those of Iₑ, the value of I_{f} was approximately one tenth or less of that of Iₑ.

### Example 3

In this example, an electron-emitting device was formed in the same manner as that in example 1 except that the step 4 of example 1 was performed as described below. Hence, hereinafter, only the step 4 will be described.

(Step 4)

In this step, 0.85 g of nickel acetate (tetrahydrate), 25 g of isopropyl alcohol, 1 g of ethylene glycol, and 0.05 g of polyvinyl alcohol were prepared, and water was added to the above compounds, thereby forming 100 g of a nickel solution. This nickel solution was applied by spin coating onto the substrate 1 which was processed by the steps until the step 3 (FIG. 1D′). Subsequently, after baking was performed at 350° C. for 30 minutes in the air, reduction was performed at 600° C. in a hydrogen stream. The catalyst particles 5 obtained in this step were disposed with spaces of approximately 100 to 1,000 nm provided therebetween and were not substantially shifted from the positions on which the Pd particles 3 were provided in the step 3.

In addition, when catalyst particles were analyzed by an X-ray analysis, which were obtained by the steps of forming the Pd particles 3 on the TiN layer with a smaller space (at higher distribution density) therebetween than that described in the above step 3, and performing the same step as the above step 4, a peak of an alloy of Pd and Ni was observed. In addition, the ratio of the Ni contained in the alloy catalyst particle was approximately 50%. Hence, the particles 5 formed in the step 4 of this example were also estimated to be alloy particles of Pd and Ni.

When the electron emission properties of the electron-emitting device obtained in this example were measured in the same manner as that in example 1, the properties of I_{f} and Iₑ were as shown in FIG. 4. That is, Iₑ was rapidly increased at an approximately half of the applied drive voltage, i.e., 10V, and when V_{f} was 20 V, approximately 0.8 μA was measured as the electron emission current Iₑ. On the other hand, although the properties of I_{f} were similar to those of Iₑ, the value of I_{f} was approximately one tenth or less of that of Iₑ.

### Example 4

In this example, an electron-emitting device was formed in the same manner as that in example 1 except that the steps 3 and 4 of example 1 were performed as described below. Hence, hereinafter, only the steps 3 and 4 will be described.

(Step 3)

As the conductive material layer, the TiN layer 15 was formed. Subsequently, 1.3 g of iron acetylacetonate was prepared, and toluene was then added thereto, thereby forming 100 g of an iron solution. Next, this iron solution was applied onto the TiN layer 15 by spin coating, followed by heating treatment at 6.00° C. under a vacuum condition. By this step, a thin film of Fe which was the first catalyst material was formed on the TiN layer 15. (Step 4)

Next, an ethanol dispersion (content of Pd: 0.2 mmol/l, particle diameter:—approximately 10 nm, a dispersing agent, PVP, dispersion medium (solvent): ethanol) of palladium particles 3, which were the particles containing the second catalyst material, was applied onto the TiN layer 15 by spin coating. Subsequently, baking was performed at 350° C. for 10 minutes in the air, and reduction treatment was then performed at 600° C. in a hydrogen stream.

In this case, the spaces between the particles 5 obtained in this example were 100 to 1,000 nm.

In addition, when catalyst particles were analyzed by an X-ray analysis, which were obtained by the steps of forming Pd particles on a thin Fe film with a smaller space (at higher distribution density) therebetween than that of the Pd particles 3 dispersedly disposed in the above step 4, and performing the same step as the above step 4, peaks of Pd and Fe were not observed, thereby confirming the presence of an alloy of Pd and Fe. In addition, with respect to the Pd contained in the alloy catalyst particle, the ratio of the Fe contained therein was 40%. Hence, the particles 5 formed in the step 4 of this example were also estimated to be alloy particles of Pd and Fe.

The Iₑ and I_{f} properties of the electron-emitting device obtained in this example were as shown in FIG. 4. That is, Iₑ was rapidly increased at an approximately half of the applied drive voltage, i.e., Vf=10V, and when V_{f} was 20 V, approximately 0.8 μA was measured as the electron emission current Iₑ. On the other hand, although the properties of I_{f} were similar to those of Iₑ, the value of I_{f} was approximately one tenth or less of that of Iₑ.

Compared to the electron-emitting devices obtained in examples 1 and 2, the electron-emitting devices of examples 3 and 4 had a large variation in time of the electron emission properties.

### Example 5

In this example, when an electron source was formed using a plurality of electron-emitting devices which were formed by the manufacturing method described in example 1 and which were disposed in matrix as shown in FIG. 8, and when the image display device 131 shown in FIG. 9 was formed by using this electron source, a display image having a high brightness could be obtained.

In the present invention described above, for example, the dimensions, materials, shapes, relative positions, and the like of the constituent elements, and the manufacturing steps are not limited to those described above, unless particularly stated otherwise. In addition, various modifications and changes may be made without departing from the spirit and the scope of the present invention.

While the present invention has been described with reference to exemplary embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadest interpretation so as to encompass all such modifications and equivalent structures and functions.

This application claims priority from Japanese Patent Application No. 2004-185026 filed Jun. 23, 2004, which is hereby incorporated by reference herein.

1. A method for manufacturing a carbon fiber, comprising:
a first step of bringing a first catalyst material into contact with a particulate second catalyst material on a substrate, the first catalyst material and the second catalyst material being different from each other;
a second step of causing the first catalyst material and the second catalyst material to react with each other to form a catalyst particle on the substrate; and
a third step of growing the carbon fiber on the substrate using the catalyst particle.

2. The method for manufacturing a carbon fiber, according to claim 1,
wherein said first step comprises:
a first substep of disposing the first catalyst material on the substrate to form a film; and
a second substep of disposing a particle containing the second catalyst material on the first catalyst material.

3. The method for manufacturing a carbon fiber, according to claim 1,
wherein said first step comprises:
a first substep of disposing a particle containing the second catalyst material on the substrate; and
a second substep of disposing the first catalyst. material so as to cover the particle.

4. The method for manufacturing a carbon fiber, according to claim 3,
wherein said first step comprises the step of bringing a magnetic first catalyst material into contact with a particulate, non-magnetic second catalyst material.

5. The method for manufacturing a carbon fiber, according to claim 3,
wherein said first substep comprises a step of disposing a plurality of particles on the substrate, each of which contains the second catalyst material, and
wherein said second substep comprises a step of disposing the first catalyst material so that the particles are not connected with each other through the first catalyst material.

6. The method for manufacturing a carbon fiber, according to claim 5,
wherein said second substep further comprises a step of precipitating the first catalyst material on the particles by bringing the particles into contact with a solvent containing the first catalyst material.

7. The method for manufacturing a carbon fiber, according to claim 1,
wherein said first step comprises the step of bringing an iron-containing, a nickel-containing, or a cobalt-containing first catalyst material into contact with a palladium-containing second catalyst material.

8. The method for manufacturing a carbon fiber, according to claim 1,
wherein said second step comprises a step of forming a catalyst particle comprising an alloy composed of the first catalyst material and the second catalyst material.

9. A method for manufacturing an electronic device having a carbon fiber, comprising:
a step of manufacturing at least one component of the electronic device; and
a step of manufacturing the carbon fiber comprising:
a first step of bringing a first catalyst material into contact with a particulate second catalyst material on a substrate, the first catalyst material and the second catalyst material being different from each other;
a second step of causing the first catalyst material and the second catalyst material to react with each other to form a catalyst particle on the substrate; and
a third step of growing the carbon fiber on the substrate using the catalyst particle.

10. A method for manufacturing an electron-emitting device having a carbon fiber, comprising:
a step of forming the carbon fiber comprising:
a first step of bringing a first catalyst material into contact with a particulate second catalyst material on a substrate, the first catalyst material and the second catalyst material being different from each other;
a second step of causing the first catalyst material and the second catalyst material to react with each other to form a catalyst particle on the substrate; and
a third step of growing the carbon fiber on the substrate using the catalyst particle; and
a step of manufacturing at least one additional component of the electron-emitting device configured and positioned to cause electrons to be emitted from the carbon fiber.

11. A method for manufacturing an image display device, comprising the steps of:
manufacturing a plurality of electron-emitting devices each of which is manufactured by:
a step of forming a carbon fiber comprising:
a first step of bringing a first catalyst material into contact with a particulate second catalyst material on a substrate, the first catalyst material and the second catalyst material being different from each other;
a second step of causing the first catalyst material and the second catalyst material to react with each other to form a catalyst particle on the substrate; and
a third step of growing the carbon fiber on the substrate using the catalyst particle; and
a step of manufacturing at least one additional component of the electron-emitting device configured and positioned to cause electrons to be emitted from the carbon fiber; and
manufacturing a light-emitting member emitting light in response to irradiation with electrons emitted from said plurality of electron-emitting devices.

12. A method of manufacturing an information display reproduction apparatus, comprising the steps of:
manufacturing a receiver which outputs at least one of an image signal, a character signal, and an audio signal contained in a received broadcasting signal; and
manufacturing an image display device connected to the receiver and displaying an image in response to receiving the image signal or the character signal from the receiver,
wherein said image-display-device manufacturing step comprises the steps of:
manufacturing a plurality of electron-emitting devices each of which is manufactured by:
a step of forming a carbon fiber comprising:
a first step of bringing a first catalyst material into contact with a particulate second catalyst material on a substrate, the first catalyst material and the second catalyst material being different from each other;
a second step of causing the first catalyst material and the second catalyst material to react with each other to form a catalyst particle on the substrate; and
a third step of growing the carbon fiber on the substrate using the catalyst particle; and
a step of manufacturing at least one additional component of the electron-emitting device configured and positioned to cause electrons to be emitted from the carbon fiber; and
manufacturing a light-emitting member emitting light in response to irradiation with electrons emitted from said plurality of electron-emitting devices.

13. An image display reproduction apparatus, comprising:
a receiver configured to output at least one of an image signal, a character signal, and an audio signal contained in a received broadcast signal; and
an image display device connected to said receiver and configured to display an image in response to receiving the image signal or the character signal from said receiver,
said image display device being manufactured according to the steps of:
manufacturing a plurality of electron-emitting devices each of which is manufactured by:
a step of forming a carbon fiber comprising:
a first step of bringing a first catalyst material into contact with a particulate second catalyst material on a substrate, the first catalyst material and the second catalyst material being different from each other;
a second step of causing the first catalyst material and the second catalyst material to react with each other to form a catalyst particle on the substrate; and
a third step of growing the carbon fiber on the substrate using the catalyst particle; and
a step of manufacturing at least one additional component of the electron-emitting device configured and positioned to cause electrons to be emitted from the carbon fiber; and
manufacturing a light-emitting member emitting light in response to irradiation with electrons emitted from said plurality of electron-emitting devices.
